(19) United States
(12) Patent Application Publication
(10) Pub. No.: US 2007/0184600 A1
(43) Pub. Date: Aug. 9, 2007

(54) Stressed-channel CMOS transistors

(75) Inventors: Da Zhang, Austin, TX (US); Michael A. Mendicino, Austin, TX (US); Bich-Yen Nguyen, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor

(21) Appl. No.: 11/348,034

(22) Filed: Feb. 6, 2006

(51) Int. Cl. H01L 21/8238

(52) U.S. Cl. 438/199; 257/E29.297

(57) ABSTRACT

Methods for forming portions of source and drain (S/D) regions of a first ensuing transistor (40) to include a semiconductor material (47) having a different composition of non-dopant elements than portions of S/D regions (35) of a second ensuing transistor (30) of opposite conductivity type are provided. The methods additionally include forming another semiconductor material (48) upon at least one set of the S/D regions of the ensuing transistors such that S/D surface layers of the ensuing transistors include substantially the same composition of non-dopant elements. A resulting semiconductor topography includes a pair of CMOS transistors (30, 40) collectively having S/D region surfaces with substantially the same composition of non-dopant elements. The S/D regions of one transistor (40) of the pair of CMOS transistors includes an underlying layer (47) having a different composition of non-dopant elements than underlying layers of the S/D regions (35) of the other transistor (30).

### BACKGROUND OF THE INVENTION

1. Field of the Invention

This invention generally relates to semiconductor processing and, more specifically, to methods for fabricating source and drain regions of CMOS transistors.

2. Description of the Related Art

The following descriptions and examples are not admitted to be prior art by virtue of their inclusion within this section.

Complementary metal oxide semiconductor (CMOS) field effect transistors (hereinafter referred to as “CMOS transistors”) are commonly employed within integrated circuits. They refer to both p-type MOS (PMOS) transistors and n-type MOS (NMOS) transistors fabricated on the same chip. Due to their opposing conductivity types, NMOS and PMOS transistors may be affected differently by fabrication techniques used to advance the performance of a circuit. For example, the process of fabricating source and drain regions of a transistor with a different material than its channel region to induce a strain within the channel may enhance the performance of a transistor of one conductivity type, but may degrade the performance of a transistor of the opposite conductivity type. In particular, altering the material of source and drain regions to induce compressive stresses within channels of transistors may enhance the performance of PMOS transistors, but in contrast may degrade the performance of NMOS transistors. In addition, altering the material of source and drain regions to induce tensile stresses within channels of transistors may enhance the performance of NMOS transistors, but in contrast may degrade the performance of PMOS transistors.

In an attempt to prevent such a variation of performance among CMOS transistors, fabrication processes used to induce stresses within channels may be restricted to transistors of one conductivity type. Such a selective practice, however, induces a variation of surface materials among source and drain regions of CMOS transistors. In particular, a typical silicidation process performed subsequent to source and drain formation includes the deposition of the same type of metal (e.g., nickel) upon source and drain regions of CMOS transistors. Consequently, the metal reacts with two types of semiconductor materials to form contacts. When the silicidation process is optimized for one type of semiconductor material within source and drain regions of one of the CMOS transistors, it typically degrades the other of the CMOS transistors. The degradation can be a substantial increase of the resistance of the silicide film to significantly impact the CMOS system performance. Thus, regardless of whether source and drain regions of PMOS and NMOS transistors are selectively or mutually altered to induce stresses within transistor channels, it is difficult to fabricate a CMOS circuit with transistors having stressed-channels without affecting the performance of the circuit.

### BRIEF DESCRIPTION OF THE DRAWINGS

Other objects and advantages of the invention will become apparent upon reading the following detailed description and upon reference to the accompanying drawings in which:

FIG. 1 depicts a partial cross-sectional view of a semiconductor topography having gates of ensuing CMOS transistors formed upon a semiconductor layer;

FIG. 2 depicts a partial cross-sectional view of the semiconductor topography in which a masking layer is formed over one of the ensuing CMOS transistors and source and drain regions are formed within the other of the ensuing CMOS transistors subsequent to the formation of the topography depicted in FIG. 1;

FIG. 3 depicts a partial cross-sectional view of the semiconductor topography in which a different masking layer and source and drain regions are respectively formed over and within the opposite ensuing CMOS transistors subsequent to the formation of the topography depicted in FIG. 2;

FIG. 4 depicts a partial cross-sectional view of the semiconductor topography in which recesses are formed within the source and drain regions of one of the ensuing CMOS transistors subsequent to their formation in FIG. 3;

FIG. 5 depicts a partial cross-sectional view of the semiconductor topography in which a first semiconductor material is formed within the recesses subsequent to their formation in FIG. 4;

FIG. 6 depicts a partial cross-sectional view of the semiconductor topography in which a second semiconductor material is formed upon the first semiconductor material subsequent to its formation in FIG. 5;

FIG. 7 depicts a partial cross-sectional view of the semiconductor topography in which metal-semiconductor alloys are formed upon the surfaces of the source and drain regions of the ensuing CMOS transistors subsequent to the formation of the second semiconductor material in FIG. 6;

FIG. 8 depicts a partial cross-sectional view of the semiconductor topography in which a semiconductor layer is formed upon the source and drain regions of one of the ensuing CMOS transistors subsequent to their formation in FIG. 2;

FIG. 9 depicts a partial cross-sectional view of the semiconductor topography in which source and drain regions are formed within the other of the ensuing CMOS transistors subsequent to the formation of the semiconductor layer in FIG. 8;

FIG. 10 depicts a partial cross-sectional view of the semiconductor topography in which metal-semiconductor alloys are formed upon the surfaces of the source and drain regions of the ensuing CMOS transistors subsequent to the formation of the source and drain regions in FIG. 9;

FIG. 11 depicts a partial cross-sectional view of the semiconductor topography in which recesses formed within the source and drain regions of one of the ensuing CMOS transistors subsequent to their formation in FIG. 2;

FIG. 12 depicts a partial cross-sectional view of the semiconductor topography in which a semiconductor material is formed within the recesses subsequent to their formation in FIG. 11;

FIG. 13 depicts a partial cross-sectional view of the semiconductor topography in which source and drain regions are formed within the other of the ensuing CMOS transistors subsequent to the formation of the semiconductor material in FIG. 12;

FIG. 14 depicts a partial cross-sectional view of the semiconductor topography in which a semiconductor layer is formed upon the source and drain regions of both ensuing CMOS transistors subsequent to the formation of the source and drain regions in FIG. 13;

FIG. 15 depicts a partial cross-sectional view of the semiconductor topography in which metal-semiconductor alloys are formed upon the surfaces of the source and drain regions of the ensuing CMOS transistors subsequent to the formation of the semiconductor layer in FIG. 14; and

FIG. 16 depicts a partial cross-sectional view of the semiconductor topography in which a semiconductor layer is formed upon the source and drain regions of one of the ensuing CMOS transistors subsequent to the formation of the source and drain regions in FIG. 13.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

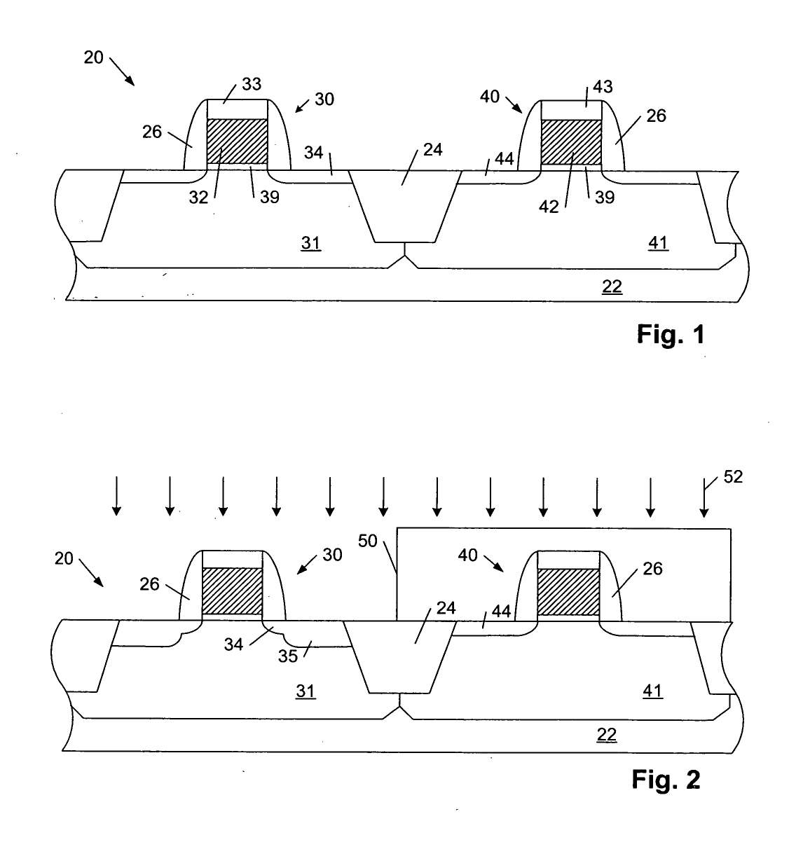

With regard to the drawings, exemplary methods for fabricating stressed-channel CMOS transistors with source and drain surfaces having a comparable composition of non-dopant elements are described below. In particular, a plurality of methods for fabricating at least one transistor of a pair of NMOS and PMOS transistors (hereinafter referred to as a pair of CMOS transistors) with a stressed channel and further fabricating the source and drain regions of the pair of CMOS transistors to collectively have a comparable composition of non-dopant elements are described in reference to FIGS. 1-15. As shown in FIG. 1, the methods may include fabricating portions of ensuing CMOS transistors 30 and 40 upon and within semiconductor layer 22 of semiconductor topography 20. In particular, the methods may include the formation of well regions 31 and/or 41, gate dielectrics 39 and 49, gate electrodes 32 and 42, cap layers 33 and 43, and extension regions 34 and 44. In addition, the methods may include the formation of isolation region 24 between ensuing CMOS transistors 30 and 40 and spacers 26 along the sidewalls of gate electrodes 32 and 42. The fabrication of such components may generally follow methods known in the semiconductor industry and, therefore, are not described herein for the sake of brevity. In addition, the compositions of the components may be any of those known in the semiconductor industry and, therefore, are not necessarily limited to the descriptions noted below.

In general, semiconductor layer 22 may include a semiconductor material. In particular, semiconductor layer 22 may, in some embodiments, be a wafer of a semiconductor material. Alternatively, semiconductor layer 22 may be a semiconductor-on-insulator (SOI) substrate, where a thin layer of a semiconductor material is arranged upon an insulating material such as silicon oxide or glass. As used herein, a semiconductor material may generally refer to a material with electrical conductivity between that of a conductor and that of an insulator through which conduction takes place by movement of holes and electrons. Although dopants may be used to vary the conductivity of a semiconductor material, such levels of conductivity are generally between those of a conductor and an insulator.

In some embodiments, a semiconductor material may be described in reference to its non-dopant elements, independent of the type and concentration of dopants included therein, if any. More specifically, a semiconductor material may be described as a material in which its one or more non-dopant elements are selected essentially from Group IV of the periodic table or, alternatively, may refer to a material in which its plurality of synthesized non-dopant elements are selected from Groups II through VI of the periodic table. Examples of Group IV semiconductor materials which may be suitable for semiconductor layer 22 include silicon, germanium, mixed silicon and germanium (“silicon-germanium”), mixed silicon and carbon (“silicon-carbon”), mixed silicon, germanium and carbon (“silicon-germanium-carbon”), and the like. Examples of Group III-V materials suitable for semiconductor layer 22 include gallium arsenide, aluminum gallium arsenide, indium gallium arsenide, and the like. Other semiconductor materials are also possible for semiconductor layer 22. It is noted that the nomenclature of semiconductor materials may generally refer to the non-dopant compositions of the materials consisting essentially of the referenced elements, but the materials are not restrained from having non-dopant impurities and/or dopants therein. For example, silicon-germanium has a non-dopant composition consisting essentially of silicon and germanium, but is not restricted to having dopants and/or impurities of other elements selected from Groups II through VI of the periodic table.

Although not necessarily limited thereto, semiconductor layer 22 may, in some embodiments, preferably include monocrystalline silicon (i.e., a material in which its non-dopant elements consist essentially of monocrystalline silicon). In particular, such a material may facilitate the formation of semiconductor materials having relatively larger and/or smaller lattice constants, such as silicon-germanium and silicon-carbon respectively, within source and drain regions of ensuing transistors 30 and/or 40 as described in more detail below. In some cases, semiconductor layer 22 may be a monocrystalline silicon wafer. In other embodiments, semiconductor layer 22 may be a silicon-on-insulator substrate, where a thin layer of monocrystalline silicon is arranged upon an insulating material such as silicon oxide or glass. Regardless of the material of semiconductor layer 22, the portion of semiconductor layer 22 underlying well regions 31 and 41 may be substantially undoped or may be doped either n-type or p-type.

By design, ensuing CMOS transistors 30 and 40 are of opposite conductivity type and, as a consequence, well regions 31 and 41 and extension regions 34 and 44 within semiconductor layer 22 are of opposite conductivity type. More specifically, well region 31 and extension regions 34 may each include a majority concentration of impurities of opposite conductivity type than the majority concentration of impurities within well region 41 and extension regions 44, respectively. In particular, an NMOS transistor may be formed within a p-type well and with n-type extension regions and vice versa for a PMOS transistor. The order in which the source and drain regions are subsequently formed within ensuing CMOS transistors 30 and 40 are not specific to their conductivity type and, thus, the conductivity types of ensuing CMOS transistors 30 and 40 are not specified relative to FIGS. 1-15. Such ambiguity emphasizes that the methods described herein may be used to form a PMOS transistor and/or an NMOS transistor with a stressed channel.

In any case, it is noted that semiconductor layer 22 may, in some embodiments, include a different composition of diffusion regions than those shown in FIG. 1. For example, one of well regions 31 and 41 may be omitted from semiconductor topography 20 in some cases. In particular, in embodiments in which semiconductor layer 22 is doped, the well region having the same type of conductivity as the semiconductor layer 22 may, in some embodiments, be omitted. In addition or alternatively, although extension regions 34 and 44 may increase the hot-carrier reliability of ensuing transistors 30 and 40, extension regions 34 and 44 may be omitted from semiconductor topography 20 in some cases. Furthermore, semiconductor layer 22 may, in some embodiments, include additional diffusion regions, such as halo regions, buried layers and/or channel stop regions. Such additional diffusion regions are not shown in FIGS. 1-15 to simplify the drawings and, therefore, should not be presumed to be necessarily omitted.

Gate electrodes 32 and 42 may include any number of conductive layers. In some cases, the conductive layers may include conductive materials, such as but not limited to doped amorphous silicon, doped polysilicon, or any metal (e.g., tantalum, titanium, tungsten), including any metal alloy, nitride or silicide thereof. In addition or alternatively, the conductive layers may include materials to be made conductive by subsequent implantation/s of dopants, such as undoped polysilicon, for example. In any case, as shown in FIG. 1, gate dielectric 39 may be interposed between well region 31 and gate 32 and gate dielectric 49 may be interposed between well region 41 and gate 42. In general, gate dielectrics 39 and 49 may include any dielectric material, such as silicon dioxide, silicon nitride, silicon oxynitride, or any multi-layer combination thereof. In some cases, cap layers 33 and 43 may be respectively formed upon gate electrodes 32 and 42 to protect upper surfaces of the gate electrodes from subsequent fabrication of overlying layers and structures. Exemplary materials which may be used for cap layers 33 and 42 include but are not limited to silicon dioxide, silicon nitride, and silicon oxynitride. In some embodiments, however, cap layers 33 and 43 may be omitted from semiconductor topography 20.

In any case, isolation region 24 may be formed of any material and thickness sufficient to isolate ensuing CMOS transistors 30 and 40, such as silicon dioxide, for example. Furthermore, sidewalls spacers 26 may be formed of any material and thickness to prevent subsequent source and drain dopant implants and, in some cases, subsequent etching processes from affecting underlying portions of extension regions 34 and 44. Exemplary materials for sidewall spacers 26 include but are not limited to silicon dioxide, silicon nitride, and silicon oxynitride. In embodiments in which extension regions 34 and 44 are omitted from semiconductor topography 20, sidewall spacers 26 may be omitted as well and, therefore, the subsequent formation of source and drain regions for ensuing CMOS transistors 30 and 40 as described in detail below may alternatively be formed aligned with gate electrodes 32 and 42.

Although the methods described herein for the subsequent fabrication of the source and drain regions of ensuing CMOS transistors 30 and 40 are based upon the prior fabrication of the components shown in FIG. 1, the methods are not necessarily so limited. In particular, the methods described herein may be combined with other known sequences of process steps for forming source and drain regions of CMOS transistors. For example, one or more of the components shown in FIG. 1 may be formed as a sacrificial structure slated to be removed during or after the fabrication of the source and drain regions and replaced by other structures thereafter. In addition or alternatively, additional components may be formed prior to, during, or subsequent to the fabrication of the source and drain regions. Furthermore, one or more of the components depicted in FIG. 1 may be omitted from semiconductor topography 20 such as noted above. Consequently, the methods described herein are not necessarily restricted to the depictions of the semiconductor topographies illustrated in FIGS. 1-15.

Turning to FIG. 2, portions of semiconductor topography 20, particularly regions comprising components of ensuing CMOS transistor 40, may be masked by masking layer 50 such that dopants 52 may be implanted into semiconductor topography 20 without diffusing into extension region 44 and well region 41. In alternative embodiments, masking layer 50 may be formed over components of ensuing CMOS transistor 30 such that dopants may be prevented from being implanted into extension region 34 and well region 31. In particular, the method described herein is not specific to the order in which source and drain regions are formed for ensuing transistors 30 and 40 and, therefore, may differ from the sequence of steps illustrated in FIGS. 1-15. In general, masking layer 50 may include a photoresist, such as a deep ultraviolet resist, an I-line resist, a G-line resist, or another resist, such as an e-beam resist or an x-ray resist. The thickness of masking layer 50 may generally be between approximately 2000 angstroms and approximately 10,000 angstroms, however, larger or smaller thicknesses may be used.

As shown in FIG. 2, the implantation of dopants 52 may form source and drain regions 35 within well region 31 aligned with sidewall spacers 26 along gate electrode 32 and adjacent portions of isolation region 24. Dopants 52 may include ions of the same conductivity type as used to create lightly doped regions 34. Exemplary p-type dopants may include but are not limited to boron containing materials and exemplary n-type dopants may include but are not limited to phosphorus or arsenic containing materials. In general, dopants 52 may be implanted at a sufficient energy such that source and drain regions 35 are formed to a depth within design specifications of the device. For example, dopants 52 may be implanted at energies between approximately 5 KeV and approximately 30 KeV. In addition, the dose of dopants 52 may generally be between approximately 1×10¹⁵ cm⁻² and approximately 1×10¹⁶ cm⁻². Larger or smaller ion doses and/or energies, however, may be used to form source and drain regions 35 in some embodiments, depending on the design specifications of the device and the conductivity type of the dopants. In some embodiments, the implantation of dopants 52 may include implanting dopants 52 into regions of gate electrode 32, particularly in but not necessarily limited to embodiments in which cap layer 33 is omitted from semiconductor topography 20. Such an implantation of dopants may, for example, transpose undoped polysilicon regions of gate electrode 32 into conductive materials and/or increase the conductivity of doped polysilicon regions within gate electrode 32.

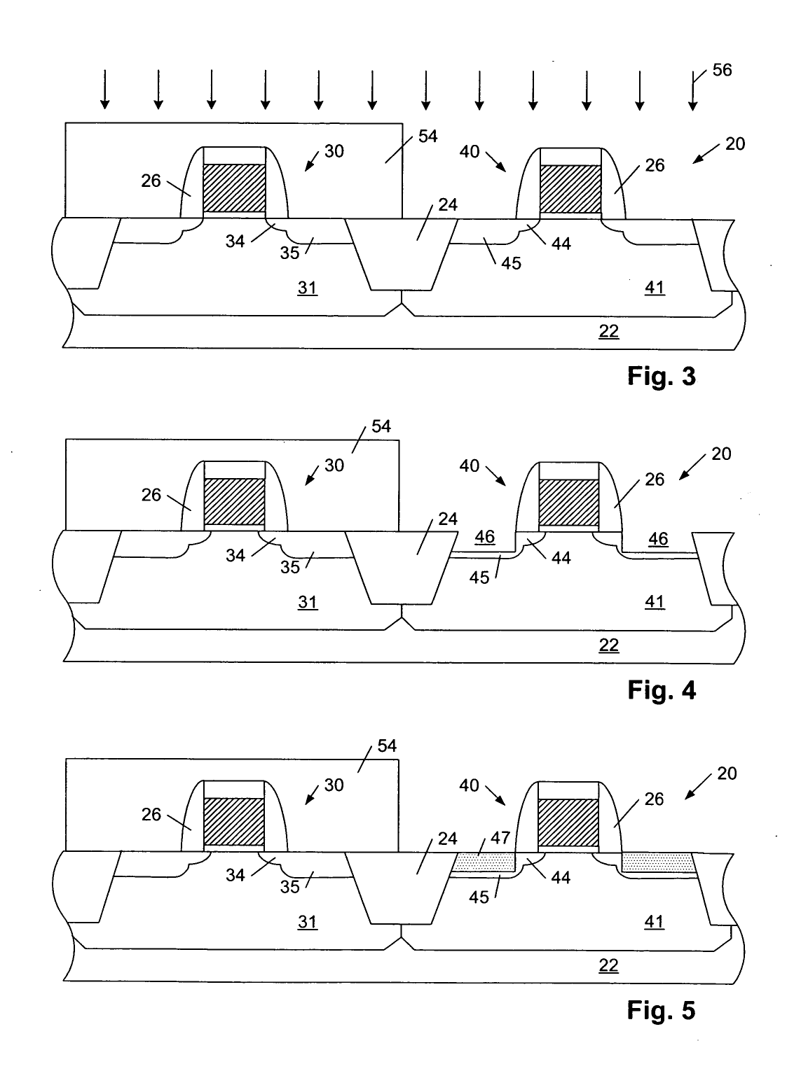

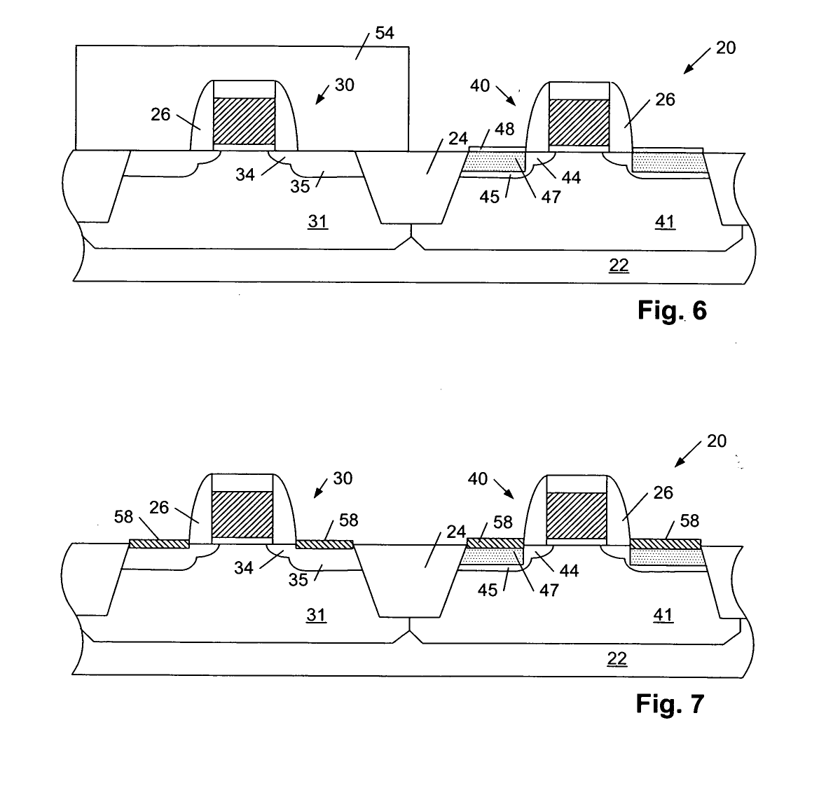

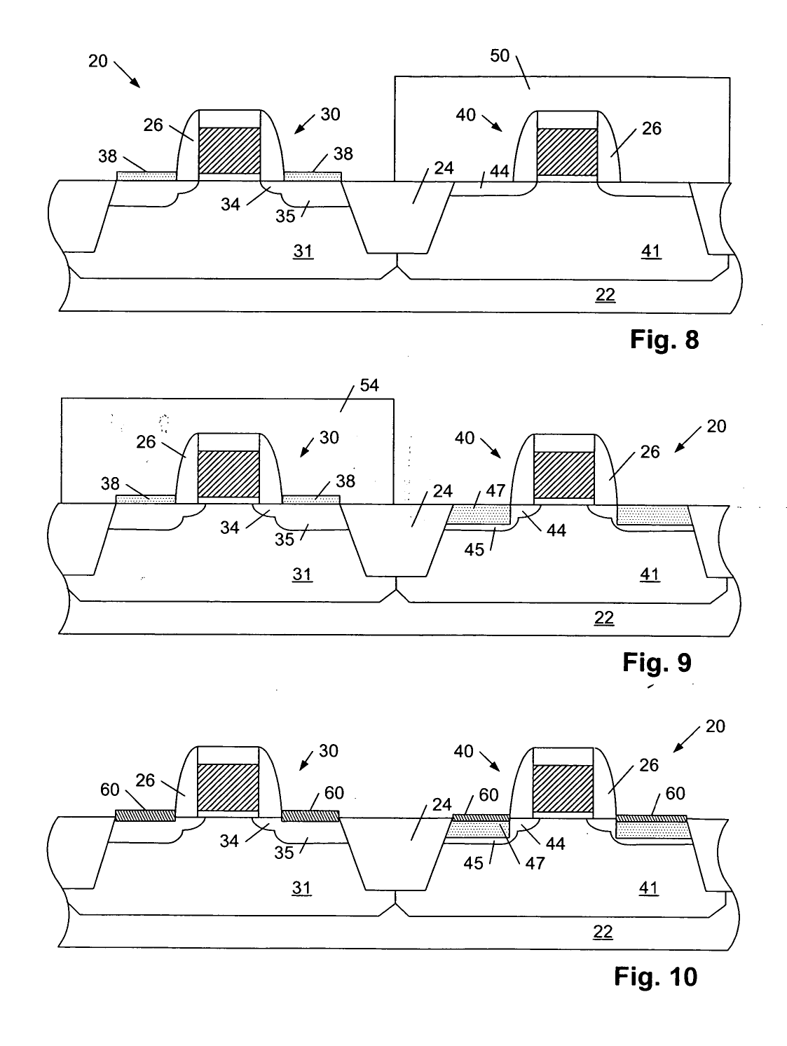

In some embodiments, the formation of source and drain regions 35 may be performed subsequent to the formation of source and drain regions in ensuing CMOS transistor 40 (which is described in reference to FIGS. 3-6). In particular, the method may alternatively run from FIG. 1 to FIG. 3 and the processes described in reference to FIG. 2 may alternatively be performed between the processes described in reference to FIGS. 6 and 7. In either case, the formation of source and drain regions in ensuing CMOS transistor 30 is not necessarily limited to the formation of source and drain regions 35 as depicted in FIG. 2. In particular, one or more additional layers may be formed upon source and drain regions 35, such as described in reference to FIG. 8 below. In addition or alternatively, portions of source and drain regions 35 may be replaced with a semiconductor material different than the channel region of ensuing CMOS transistor 30. An exemplary sequence of steps which may be used to replace portions of source and drain regions 35 with a different semiconductor material than the channel region of ensuing CMOS transistor 30 is described below in reference to FIGS. 11 and 12. In general, the channel region of a transistor as used herein may refer to the region of the semiconductor substrate underlying the gate structure of the transistor or, more specifically, the region of the semiconductor substrate interposed between diffusion regions arranged on opposing sides of the gate. As such, the channel region of ensuing CMOS transistor 30 may refer to the region of semiconductor layer 22 interposed between extension regions 34. Likewise, the channel region of ensuing CMOS transistor 40 may refer to the region of semiconductor layer 22 interposed between extension regions 44.

As shown in FIG. 3, masking layer 50 may be removed from semiconductor topography 20 subsequent to the implantation of dopants 52 described in reference to FIG. 2 in embodiments in which source and drain regions 35 are formed prior to the source and drain regions of ensuing CMOS transistor 40. Subsequent thereto, masking layer 54 may be formed over portions of semiconductor topography 20, particularly regions comprising components of ensuing CMOS transistor 30, such that dopants 56 may be implanted into semiconductor topography 20 without diffusing into extension region 34 and well region 31. As shown in FIG. 3, dopants 56 may be implanted into portions of well region 41 to form source and drain regions 45 aligned with sidewall spacers 26 along gate electrode 42 and adjacent portions of isolation region 24. In some embodiments, the implantation of dopants 56 may further include implanting dopants 56 into regions of gate electrode 42, particularly in but not necessarily limited to embodiments in which cap layer 43 is omitted from semiconductor topography 20. Such an implantation of dopants may, for example, transpose undoped polysilicon regions of gate electrode 42 into conductive materials and/or increase the conductivity of doped polysilicon regions within gate electrode 42. In general, masking layer 54 may include similar materials and thicknesses as described for masking layer 50. In addition, dopants 56 may include ions of the same conductivity type as used to create extension regions 44 and, therefore, may of opposite conductivity type as dopants 52. The energies, doses, and depths to which dopants 56 may be implanted within well region 41 may generally be similar to those recited above for the implantation of dopants 52.

Subsequent to the formation of source and drain regions 45, semiconductor topography 20 may be annealed to activate the implanted impurities and eliminate defects created by implantations of dopants 52 and/or 56. In some embodiments, the anneal process may be a rapid thermal anneal (RTA) process. In particular, the anneal process may expose semiconductor topography 20 to a relatively high temperature, such as between approximately 900° C. and approximately 1100° C., for less than a minute and, more preferably for approximately 20 seconds or less. Higher or lower temperatures and/or longer or short durations, however, may be employed for the anneal process in some embodiments, depending on the design specifications of the topography. As shown in FIG. 4, the anneal process causes boundaries of source and drain regions 35 and 45 and extension regions 34 and 44 to expand deeper into well regions 31 and 41 and laterally under gate electrodes 32 and 42, respectively. It is noted, that the depths of source and drain regions 35 and 45 and extension regions 34 and 44 may increase slightly with subsequent anneal processes, but such a variation of depths are not shown in succeeding figures.

As further shown in FIG. 4, the process may continue by etching recesses 46 within source and drain regions 45. In some cases, the formation of recesses 46 may include the formation of a masking layer over regions of semiconductor topography 20 not including exposed surfaces of source and drain regions 45 to protect such surfaces from subsequent wet or dry etch techniques used to form recesses 46. In other embodiments, etch chemistries which are particularly selective to the semiconductor material of semiconductor layer 22 over other materials of semiconductor topography 20 may be used to form recesses 46 without a masking layer. In some embodiments, it may be advantageous to use selective chemistries to avoid time-consuming and costly steps of removing masking layer 54 and/or forming an additional photolithographic masking layer to cover areas of semiconductor topography 20 adjacent to source and drain regions 45. As shown in FIG. 4, the depths of recesses 46 may slightly shallower than the depths of source and drain regions 45, but recesses 46 are not necessarily so limited. In particular, recesses 46 may be formed to a depth greater than source and drain regions 45 or may be formed to a shallower depth than depicted in FIG. 4.

Subsequent to the formation of recesses 46, semiconductor material 47 may be formed by epitaxy therein as shown in FIG. 5. In general, semiconductor material 47 may include a semiconductor material having a lattice constant that is different from that of semiconductor layer 22 to alter the stress within the channel region of ensuing CMOS transistor 40. In particular, in embodiments in which ensuing CMOS transistor 40 is an ensuing PMOS transistor, semiconductor material 47 may include a semiconductor material with a lattice constant larger than the lattice constant of semiconductor layer 22. In such embodiments, semiconductor material 47 creates a compressive stress within the channel of ensuing CMOS transistor 40 which, in turn, increases hole mobility within the channel. As a result, significant improvements in drain current of the ensuing PMOS transistor may be realized. In embodiments in which using CMOS transistor 40 is an ensuing NMOS transistor, semiconductor material 47 may include a semiconductor material with a lattice constant smaller than the lattice constant of semiconductor layer 22. In such embodiments, semiconductor material 47 creates a tensile stress within the channel of ensuing CMOS transistor 40 which, in turn, increases electron mobility within the channel. As a result, significant improvements in drain current of the ensuing NMOS transistor may be realized. In general, the size of lattice constants in a material may refer to the spacing of repeatable patterns of atoms within the material.

An example of a material for inducing a compressive stress within a monocrystalline silicon channel of an ensuing CMOS transistor may be silicon-germanium. As such, in some embodiments, semiconductor layer 22 and semiconductor material 47 may include monocrystalline silicon and silicon-germanium, respectively. In such cases, a material having an atomic percentage between approximately 15% and approximately 50% germanium may be particularly suitable for inducing compressive stress within the channel region of ensuing CMOS transistor 40. In contrast, an example of a material for creating a tensile stress within a monocrystalline silicon channel of an ensuing CMOS transistor may be silicon-carbon. Consequently, in some embodiments, semiconductor layer 22 and semiconductor material 47 may includes monocrystalline silicon and silicon-carbon, respectively. Other materials for semiconductor material 47, however, may be employed to induce a compressive or tensile stress within a monocrystalline silicon layer. In addition, as noted above, semiconductor layer 22 is not restricted to being a monocrystalline silicon substrate and, therefore, a plurality of different combinations of materials for semiconductor layer 22 and semiconductor material 47 are possible, such as from the lists noted below.

In any case, semiconductor material 47 may generally be described as including a semiconductor material having a different composition of non-dopant elements (i.e., regardless of the type and concentration of dopants included therein) than semiconductor layer 22. As such, semiconductor material 47 may have a different composition of non-dopant elements than the channel region of ensuing CMOS transistor 40. In addition, semiconductor material 47 may have a different composition of non-dopants element than source and drain regions 35 of ensuing CMOS transistor 30. In particular, semiconductor material 47 may include one or more elements selected from Group II through VI of the periodic table which are different from the one or more elements selected from Group II through VI of the periodic table comprising semiconductor layer 22. In addition or alternatively, semiconductor layer 22 may include one or more elements selected from Group II through VI of the periodic table which are different from the one or more Group II through VI elements comprising semiconductor material 47. As noted above, examples of Group IV semiconductor materials include silicon, germanium, mixed silicon and germanium (“silicon-germanium”), mixed silicon and carbon (“silicon-carbon”), mixed silicon, germanium and carbon (“silicon-germanium-carbon”), and the like. In addition, examples of Group III-V materials include gallium arsenide, aluminum gallium arsenide, indium gallium arsenide, and the like.

Semiconductor material 47 may be formed in a variety of manners. For instance, semiconductor material 47 may, in some embodiments, be formed by selective epitaxial growth of semiconductor layer 22 at the bases of recesses 46. In some cases, the material grown within recesses 46 may be formed with its intended composition of non-dopant elements. Alternatively, one or more elements selected from Groups II through VI of the periodic table may be subsequently diffused within a material grown within recesses 46. In yet other cases, recesses 46 may not be formed within semiconductor topography 20 and, therefore, the process described in reference to FIG. 4 may be omitted. In such embodiments, one or more elements selected from Groups II through VI of the periodic table may be diffused within source and drain regions 35 and possibly well region 31 to form semiconductor material 47. In some cases, it may be preferable to form semiconductor material 47 with in-situ doping of preferred elements to mitigate any subsequent implantation of dopant elements. In particular, implantation processes may undesirably damage the crystalline structure of a semiconductor layer. In addition, an implantation process may require additional time-consuming and costly masking steps. Thus, it may be preferable to form semiconductor material 47 by selective epitaxial growth of semiconductor layer 22 in recesses 46 with its intended composition of non-dopant and dopant elements in some embodiments.

In any case, the process conditions used to form semiconductor material 47 may be specific to the semiconductor material being formed and, in the case of selective epitaxial growth, may depend on the material of semiconductor layer 22. Such process conditions may generally include techniques known in the semiconductor fabrication industry. For example, process conditions for growing an epitaxial silicon germanium layer from a monocrystalline silicon layer may include but are not limited to exposing the monocrystalline silicon material to an ambient having dichlorosilane, diborane, and approximately 50 sccm of germane at a temperature between approximately 400° C. and approximately 750° C. As noted above, the formation of an epitaxial silicon germanium layer may be advantageous for the fabrication of ensuing PMOS transistors in embodiments in which semiconductor layer 22 is a monocyrstalline silicon substrate. Other combinations of semiconductor materials for semiconductor material 47 and semiconductor layer 22, however, may be possible. Consequently, several other process conditions for forming semiconductor material 47 may be considered.

Turning to FIG. 6, semiconductor material 48 may be formed upon semiconductor material 47. In general, semiconductor material 48 may include the same composition of non-dopant elements as the surface layers of source and drain regions 35 of ensuing CMOS transistor 30. In this manner, the surface layers of source and drain regions of ensuing CMOS transistors 30 and 40 may include the same composition of non-dopant elements, while underlying layers of the source and drain regions may have comparatively different compositions of non-dopant elements. As described above in reference to FIG. 2, source and drain regions 35 of ensuing CMOS transistor 30 may be formed by implanting dopants 52 into well region 31, which is a doped region of semiconductor layer 22. As such, the surface of source and drain regions 35 may, in some embodiments, include the same composition of non-dopant elements as semiconductor layer 22. In turn, semiconductor material 48 may, in some cases, include the same composition of non-dopant elements as semiconductor layer 22. As noted above, semiconductor layer 22 may, in some embodiments, be a monocrystalline silicon substrate and, therefore, semiconductor material 48 may include monocrystalline silicon in some cases. Other semiconductor materials for semiconductor layer 22 and semiconductor material 48, however, may be employed.

Although selective epitaxial growth may generally be the preferred method of formation for semiconductor material 48 to avoid costly and time-consuming additional steps of mask formation and material etching, semiconductor material 48 may alternatively be formed by non-selective deposition of the material upon semiconductor topography 20 and subsequently patterning the deposited material above semiconductor material 47. In general, the thickness of semiconductor material 48 may depend on the slated thickness of a metal-semiconductor alloy subsequently formed therefrom and, therefore, may vary among different design specifications and technologies. An exemplary range of thickness of semiconductor material 48, however, may be between approximately 50 angstroms and approximately 200 angstroms, and in some embodiments, specifically around approximately 100 angstroms.

As noted above, source and drain regions 35 of ensuing transistor 30 may alternatively be formed subsequent to the formation of source and drain regions in ensuing CMOS transistor 40. In particular, the processes described in reference to FIG. 2 may alternatively be performed between the processes described in reference to FIGS. 6 and 7. As such, the method may include forming source and drain regions 35 subsequent to the formation of semiconductor material 48. In such cases, the material selected for semiconductor material 48 may include the same composition of non-dopant elements intended for source and drain regions 35 according to the design specifications of semiconductor topography 20. Regardless of the timing to which source and drain regions 35 of ensuing CMOS transistor 30 are formed relative to the formation of semiconductor material 47 in ensuing CMOS transistor 40, semiconductor material 48 may alternatively be formed upon both sets of source and drain regions of ensuing CMOS transistors 30 and 40 rather than just upon semiconductor material 47. In particular, semiconductor material 48 may be formed upon semiconductor material 47 and source and drain regions 35 after the formation of each of the respective regions or may be formed at the same time over such regions.

As shown in FIG. 7, subsequent to the formation of semiconductor material 48 described in reference to FIG. 6, metal-semiconductor alloys 58 may be formed upon the surfaces of the source and drain regions of ensuing CMOS transistors 30 and 40. In particular, a metal may be deposited upon surfaces of source and drain regions 35 and semiconductor material 48. Subsequently, semiconductor topography 20 may be annealed to induce a reaction between the metal and the semiconductor material at the surfaces of the source and drain regions to form metal-semiconductor alloys 58 (e.g., silicides). In general, the thickness of the deposited metal may depend on the slated thickness of metal-semiconductor alloys 58 and, therefore, may vary among different design specifications and technologies. An exemplary range of thickness of semiconductor material 48, however, may be between approximately 50 angstroms and approximately 200 angstroms, and in some embodiments, specifically around approximately 100 angstroms. In some embodiments, it may be advantageous for the metal to be deposited to a thickness less than or equal to the thickness of semiconductor material 48 such that the consumption of semiconductor material 47 within metal-semiconductor alloys 58 during the anneal process may be minimized. As shown in FIG. 7, the height of metal-semiconductor alloys 58 may differ among ensuing CMOS transistors 30 and 40 due to the exclusive inclusion of semiconductor material 48 within the source and drain regions of ensuing CMOS transistor 40. Such a variation of heights, however, does not significantly, if at all, affect the operation of ensuing CMOS transistors 30 and 40.

In general, any transition metal may be deposited to form metal-semiconductor alloys 58. Some particularly suitable transition metals may include but are not limited to cobalt, molybdenum, nickel, platinum, tantalum, titanium, tungsten, and any alloys thereof. In some embodiments, the method described herein may be particularly applicable when a metal which is susceptible to large variations of sheet resistance among different semiconductor materials is slated for formation of metal-semiconductor alloys 58. For example, alloys of cobalt-silicon-germanium may exhibit significantly higher sheet resistance as compared to alloys of cobalt-silicon and, as such, it may be advantageous to form surfaces of the source and drain regions of ensuing CMOS transistors 30 and 40 to include monocrystalline silicon in order to minimize the sheet resistance of metal-semiconductor alloys 58 when cobalt is employed. Other metals may have similar or different effects with semiconductor materials as well and, as such, the methods described herein are not necessarily restricted to fabrication processes in which alloys of cobalt-silicon are slated to be formed for metal-semiconductor alloys 58. It is noted that since metal-semiconductor alloys 58 include non-dopant elements other than those included in Groups II-VI of the periodic table, metal-semiconductor alloys 58 do not meet the definition of a semiconductor material as defined herein. Rather, metal-semiconductor alloys 58 are considered conductors.

An alternative sequence of process steps for fabricating at least one transistor of a pair of NMOS and PMOS transistors with a stressed channel and further fabricating the source and drain regions of the pair of CMOS transistors to collectively have a comparable composition of non-dopant elements on their respective surfaces is shown and described in reference to FIGS. 8-10. In particular, FIG. 8 illustrates semiconductor topography 20 having semiconductor material 38 formed upon the surfaces of source and drain regions 35 subsequent to their formation described in reference to FIG. 2. In other cases, semiconductor material 38 may be formed upon source and drain regions 35 subsequent to the formation of semiconductor material 47 within ensuing CMOS transistor 40 described in reference to FIG. 5. As such, the method described in reference to FIG. 8 may alternatively be performed between the processes described for FIGS. 9 and 10. In either case, as shown by the different pattern of semiconductor material 38 relative to semiconductor layer 22 in FIG. 8, semiconductor material 38 may include a different composition of non-dopant elements than the channel region of ensuing CMOS transistor 30. In some embodiments, semiconductor material 38 may include the same composition of non-dopant elements as slated for a surface portion of ensuing CMOS transistor 40. In this manner, the surface layers of source and drain regions of ensuing CMOS transistors 30 and 40 may include the same composition of non-dopant elements, while underlying layers of the source and drain regions may have comparatively different compositions of non-dopant elements.

In some cases, semiconductor material 38 may include the same composition of non-dopant elements as slated for semiconductor material 47 within the source and drain regions of ensuing CMOS transistor 40. In other words, semiconductor material 38 may include the same composition of non-dopant elements as slated for the source and drain region portions in ensuing CMOS transistor 40 which are configured to alter the stress within the channel region of the transistor. In this manner, semiconductor material 38 may be used to balance the compatibility of the source and drain region surfaces of semiconductor topography 20 for the subsequent formation of metal-semiconductor alloys. As noted above, in some embodiments, semiconductor material 47 may include silicon-germanium or silicon-carbon and, as such, semiconductor material 38 may, in some cases, respectively include silicon-germanium or silicon-carbon. Other semiconductor materials for semiconductor material 38 and semiconductor material 47, however, may be employed as described above for the formation of semiconductor material 47 in reference to FIG. 5.

Although selective epitaxial growth may generally be the preferred method of formation for semiconductor material 38 to avoid costly and time-consuming additional steps of mask formation and material etching, semiconductor material 38 may alternatively be formed by non-selective deposition of the material upon semiconductor topography 20 and subsequently patterning the deposited material above source and drain regions 35. In general, the thickness of semiconductor material 38 may depend on the slated thickness of a metal-semiconductor alloy formed therefrom and, therefore, may vary among different design specifications and technologies. An exemplary range of thickness of semiconductor material 38, however, may be between approximately 50 angstroms and approximately 200 angstroms, and in some embodiments, specifically around approximately 100 angstroms.

Subsequent or prior to the formation of semiconductor material 38, semiconductor topography 20 may be processed in a manner similar to the steps described in reference to FIGS. 3-5 to form semiconductor material 47 within the source and drain regions of ensuing CMOS transistor 40 as shown in FIG. 9. In cases in which semiconductor material 38 includes the same composition of non-dopant elements as semiconductor material 47, the formation of semiconductor material 48 described in reference to FIG. 6 may be omitted from the fabrication sequence described in reference to FIGS. 8-10. In other embodiments, however, the formation of semiconductor material 48 may be included in such a sequence. In any case, metal-semiconductor alloys 60 may be formed upon the surfaces of the source and drain regions of ensuing CMOS transistors 30 and 40 subsequent to the formation of semiconductor material 47 and semiconductor material 38 as shown in FIG. 10. In general, the fabrication process for metal-semiconductor alloys 60 may be similar to processes described for metal-semiconductor alloys 58 in reference to FIG. 7. In particular, the thickness and type of metal used may be similar to that described for metal-semiconductor alloys 58.

The processes described above in reference to FIGS. 1-10 specifically outline fabrication sequences for forming one transistor of a pair of CMOS transistors with a stressed channel. The methods described herein, however, are not necessarily so limited. In particular, other fabrication sequences which form both NMOS and PMOS transistors with stressed channels and further fabricate the source and drain regions of the pair of CMOS transistors to collectively have a comparable composition of non-dopant elements may be considered. Exemplary methods for fabricating such topographies are shown and described in reference to FIGS. 11-16.

FIG. 11 illustrates semiconductor topography 20 with recesses 36 formed within source and drain regions 35 subsequent to the formation of source and drain regions 35 described in reference to FIG. 2. In general, recesses 36 may be formed using processes and having characteristics similar to those described for the formation of recesses 46 in reference to FIG. 4. In particular, the formation of recesses 36 may include the formation of a masking layer over regions of semiconductor topography 20 not including exposed surfaces of source and drain regions 35 to protect such surfaces from subsequent wet or dry etch techniques used to form recesses 36. In other embodiments, etch chemistries which are particularly selective to the semiconductor material of semiconductor layer 22 over other materials of semiconductor topography 20 may be used to form recesses 46 without a masking layer. Following the formation of recesses 36, semiconductor material 37 may be formed therein as shown in FIG. 12. As described for semiconductor material 47 in reference to FIG. 5 for the formation of source and drain regions within ensuing CMOS transistor 40, semiconductor material 37 may include a semiconductor material having a lattice constant different from that of semiconductor layer 22 to alter the stress within the channel region of ensuing CMOS transistor 30. Semiconductor material 37, however, may differ from semiconductor material 47 by being configured to induce an opposite type of stress within the channel region of ensuing CMOS transistor 30 as compared to the stress which is induced by subsequent formation of semiconductor material 47 in ensuing CMOS transistor 40.

For example, in embodiments in which ensuing CMOS transistor 30 is an ensuing NMOS transistor and ensuing CMOS transistor 40 is an ensuing PMOS transistor, semiconductor material 37 may include a semiconductor material configured to induce a tensile stress within the channel region of the NMOS transistor and semiconductor material 47 may subsequently formed to induce a compressive stress within the channel region of the PMOS transistor. In other words, semiconductor material 37 may include a semiconductor material with a lattice constant smaller than that of semiconductor layer 22 and semiconductor material 47 may subsequently formed to include a semiconductor material with a lattice constant larger than that of semiconductor layer 22. In alternative embodiments in which ensuing CMOS transistor 30 is an ensuing PMOS transistor and ensuing CMOS transistor 40 is an ensuing NMOS transistor, the size of the lattice constants of semiconductor materials 37 and 47 may be reversed. In either case, due to the resulting increase in electron and hole mobility in the respective channels, significant improvements in drain current of the ensuing CMOS transistors may be realized.

In general, the manner in which to form semiconductor material 37 may be similar to the processes described for the formation of semiconductor material 47 in reference to FIG. 5, preferably including but not limited to selective epitaxial growth of semiconductor layer 22. Furthermore, the composition of non-dopant elements comprising semiconductor material 37 may be selected from the materials described above for semiconductor material 47 in reference to FIG. 5. As noted above, an example of a material for inducing a compressive stress within a monocrystalline silicon channel of an ensuing CMOS transistor may be silicon-germanium. As such, in some embodiments, semiconductor layer 37 may include silicon-germanium when semiconductor layer 22 includes monocrystalline silicon. As further noted above, an example of a material for creating a tensile stress within a monocrystalline silicon channel of an ensuing CMOS transistor may be silicon-carbon. Consequently, in some embodiments, semiconductor material 37 may alternatively include silicon-carbon when semiconductor layer 22 includes monocrystalline silicon. Other materials for semiconductor material 37, however, may be employed to induce a compressive or tensile stress within a monocrystalline silicon layer. In addition, as noted above, semiconductor layer 22 is not restricted to being a monocrystalline silicon substrate and, therefore, a plurality of different combinations of materials for semiconductor layer 22 and semiconductor material 37 are possible.

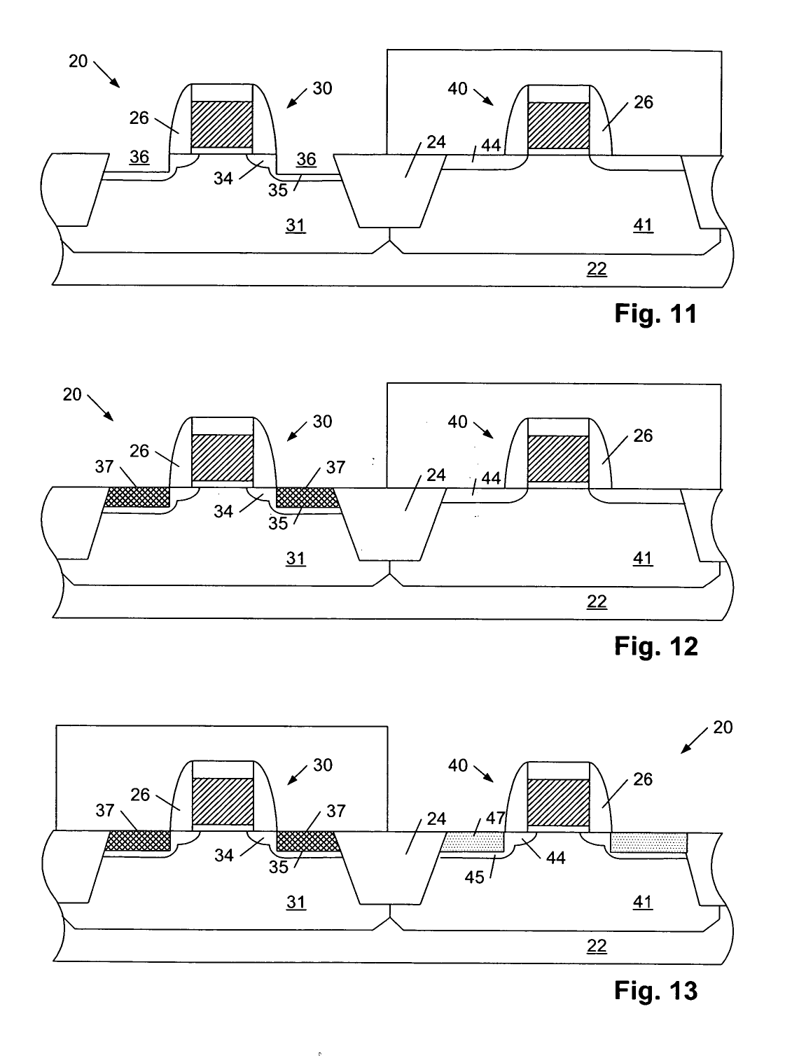

Subsequent to the formation of semiconductor material 37, semiconductor topography 20 may be processed in a manner similar to the steps described in reference to FIGS. 3-5 to form semiconductor material 47 within the source and drain regions of ensuing CMOS transistor 40 as shown in FIG. 13. As noted above, the methods described herein are not necessarily restricted to the order in which stress channel regions are formed within ensuing PMOS and NMOS transistors. As such, the conductivity type of ensuing CMOS transistors 30 and 40 and type of stress formed within their channels by semiconductor materials 37 and 47 may be interchangeably referenced. In particular, the method may apply to process sequences in which source and drain regions of an ensuing PMOS transistor are formed first followed by the formation of source and drain regions of an ensuing NMOS transistor or vice versa.

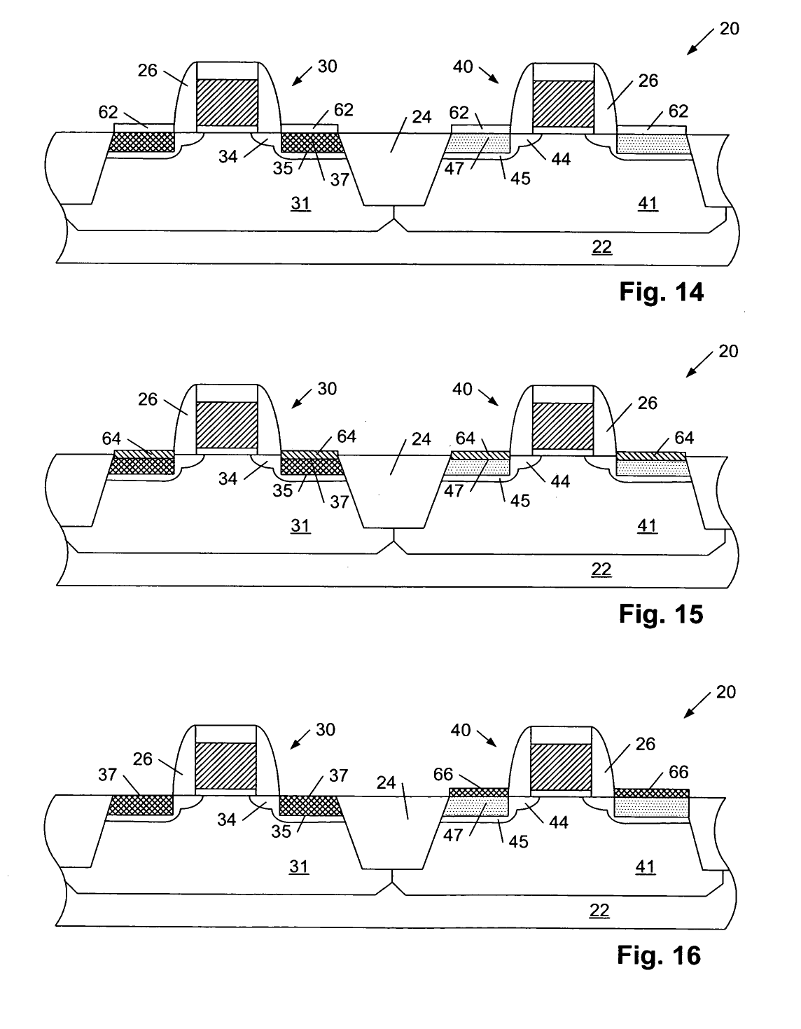

In any case, semiconductor material 62 may be formed upon the upper surfaces of semiconductor materials 37 and 47 as shown in FIG. 14. In some cases, semiconductor material 62 may be formed upon semiconductor materials 37 and 47 at the same time. In other embodiments, however, semiconductor material 62 may be formed upon semiconductor materials 37 and 47 separately and, in some cases, directly subsequent to their respective formations. In either case, semiconductor material 62 may include a substantially similar composition of non-dopant elements over semiconductor materials 37 and 47 to balance the compatibility of the source and drain region surfaces of semiconductor topography 20 for the subsequent formation of metal-semiconductor alloys. In this manner, the surface layers of source and drain regions of ensuing CMOS transistors 30 and 40 may include the same composition of non-dopant elements, while underlying layers of the source and drain regions may have comparatively different compositions of non-dopant elements.

In general, semiconductor material 62 may include any of the materials described for semiconductor layer 22 in reference to FIG. 1 or any material described for semiconductor material 47 in reference to FIG. 5. In some embodiments, semiconductor material 62 may include the same composition of non-dopant elements as semiconductor layer 22. Alternatively, semiconductor material 62 may include the same composition of non-dopant elements as semiconductor material 37 or semiconductor material 47. In other cases, semiconductor material 62 may include a different composition of non-dopant elements than semiconductor layer 22, semiconductor material 37, and semiconductor material 47. In any case, semiconductor material 62 may be formed in similar manners as described above for semiconductor materials 38 and 48 and preferably by selective epitaxial growth. In addition, the thickness of semiconductor material 62 may be similar to thickness described above for such layers. In any case, metal-semiconductor alloys 64 may be formed upon the surfaces of the source and drain regions of ensuing CMOS transistors 30 and 40 subsequent to the formation of semiconductor material 62 as shown in FIG. 15. In general, the fabrication process for metal-semiconductor alloys 62 may be similar to processes described for metal-semiconductor alloys 58 in reference to FIG. 7. In particular, the thickness and type of metal used may be similar to that described for metal-semiconductor alloys 58.

An alternative sequence of process steps for forming two CMOS transistors with stressed channels and further fabricating the source and drain regions of the pair of CMOS transistors to collectively have a comparable composition of non-dopant elements is discussed in reference to FIG. 16. In particular, FIG. 16 depicts semiconductor topography 20 having semiconductor material 66 formed upon semiconductor material 47. Such a process may be formed subsequent to the formation of both semiconductor materials 37 and 47 or prior to the formation of semiconductor material 37. In either case, semiconductor material 66 may include the same composition of non-dopant elements as slated for semiconductor material 37 to balance the compatibility of the source and drain region surfaces of semiconductor topography 20 for the subsequent formation of metal-semiconductor alloys. Alternatively, a semiconductor material including the same composition of non-dopant elements as slated for semiconductor material 47 may be formed upon semiconductor material 37. In either case, the surface layers of source and drain regions of ensuing CMOS transistors 30 and 40 may include the same composition of non-dopant elements.

In general, semiconductor material 66 may be formed in similar manners as described above for semiconductor materials 38 and 48 and preferably by selective epitaxial growth. In addition, the thickness of semiconductor material 66 may be similar to thickness described above for such layers. Subsequent to the formation of semiconductor material 66, metal-semiconductor alloys may be formed upon the surfaces of the source and drain regions of ensuing CMOS transistors 30 and 40. An exemplary resulting topography may be similar to 7 and, as such, the fabrication process for the metal-semiconductor alloys may be similar to processes described for metal-semiconductor alloys 58 in reference to FIG. 7.

It will be appreciated to those skilled in the art having the benefit of this disclosure that this invention is believed to provide methods for fabricating at least one transistor of a pair of CMOS transistors with a stressed channel and further fabricating the source and drain regions of the pair of CMOS transistors to collectively have a comparable composition of non-dopant elements. Further modifications and alternative embodiments of various aspects of the invention will be apparent to those skilled in the art in view of this description. For example, the methods described herein are not limited to process sequences illustrated in the figures, particularly in the order the source and drain regions are formed relative to the other components of a transistor. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A method for processing a semiconductor topography, comprising:
forming portions of source and drain regions of a first ensuing transistor, wherein the portions include a first semiconductor material, and wherein the first semiconductor material includes a different composition of non-dopant elements than portions of source and drain regions of a second ensuing transistor of opposite conductivity type than the first ensuing transistor; and
forming a second semiconductor material upon at least one set of the source and drain regions of the first and second ensuing transistors such that source and drain surface layers of the first and second ensuing transistors include substantially the same composition of non-dopant elements.

2. The method of claim 1, wherein the second semiconductor material includes substantially the same composition of non-dopant elements as the portions of the source and drain regions of the second ensuing transistor, and wherein the step of forming the second semiconductor material includes selectively forming the second semiconductor material upon at least the source and drain regions of the first ensuing transistor.

3. The method of claim 1, wherein the step of forming the second semiconductor material includes forming the second semiconductor material upon the source and drain regions of each of the first and second ensuing transistors.

4. The method of claim 1, wherein the first semiconductor material includes a different composition of non-dopant elements than a third semiconductor material comprising channels of the first and second ensuing transistors.

5. The method of claim 4, further comprising forming the portions of source and drain regions of the second ensuing transistor to include a fourth semiconductor material having a different composition of non-dopant elements than the third semiconductor material.

6. The method of claim 1, further comprising forming metal-semiconductor alloys upon the source and drain surface layers of the first and second ensuing transistors.

7. A method for processing a semiconductor topography, comprising:
etching recesses within regions of a semiconductor layer slated for formation of source and drain regions of a first ensuing transistor;
growing a first epitaxial semiconductor material within the recesses to alter the stress within a portion of the semiconductor layer between the recesses; and
growing a second epitaxial semiconductor material upon the first epitaxial semiconductor material, wherein the second epitaxial semiconductor material includes a different composition of non-dopant elements than the first epitaxial semiconductor material.

8. The method of claim 7, wherein the first ensuing transistor is a PMOS transistor, and wherein the step of growing the first epitaxial semiconductor material within the recesses creates compressive stress within the channel of the PMOS transistor.

9. The method of claim 8, wherein the step of etching the recesses includes etching recesses within a substrate having a non-dopant composition consisting essentially of silicon, and wherein the step of growing the first epitaxial semiconductor material includes growing the first epitaxial semiconductor material having a non-dopant composition consisting essentially of silicon and germanium.

10. The method of claim 7, wherein the first ensuing transistor is an NMOS transistor, and wherein the step of growing the first epitaxial semiconductor material within the recesses creates tensile stress within the channel of the NMOS transistor.

11. The method of claim 10, wherein the step of etching the recesses includes etching recesses within a substrate having a non-dopant composition consisting essentially of silicon, and wherein the step of growing the first epitaxial semiconductor material includes growing the first epitaxial semiconductor material having a non-dopant composition consisting essentially of silicon and carbon.

12. The method of claim 7, further comprising forming source and drain regions of a second ensuing transistor having opposite conductivity of the first ensuing transistor, wherein the second epitaxial semiconductor material includes substantially the same composition of non-dopant elements as surface layers of the source and drain regions of the second ensuing transistor.

13. The method of claim 7, further comprising:
etching recesses within regions of the semiconductor layer slated for formation of source and drain regions of a second ensuing transistor having opposite conductivity of the first ensuing transistor; and
growing a third epitaxial semiconductor material within the recesses to alter the stress within the channel of the second ensuing transistor, wherein the third epitaxial semiconductor material includes substantially the same composition of non-dopant elements as the second epitaxial semiconductor material.

14. The method of claim 7, further comprising:
etching recesses within regions of the semiconductor layer slated for formation of source and drain regions of a second ensuing transistor having opposite conductivity of the first ensuing transistor; and
growing a third epitaxial semiconductor material within the recesses to alter the stress within the channel of the second ensuing transistor, wherein the third epitaxial semiconductor material includes a substantially different composition of non-dopant elements than the first and second epitaxial semiconductor materials, and wherein the step of growing the second epitaxial semiconductor material further includes growing the second epitaxial semiconductor material upon the third epitaxial semiconductor material.

15. The method of claim 7, wherein the step of growing the second epitaxial semiconductor material includes growing the second epitaxial semiconductor material to include a non-dopant composition consisting essentially of silicon.

16. The method of claim 7, further comprising:
depositing a metal upon the second epitaxial semiconductor material; and
annealing the semiconductor topography to induce a reaction between the metal and the second epitaxial semiconductor material to form a metal-semiconductor alloy.

17. A semiconductor topography, comprising:
a pair of CMOS transistors collectively having source and drain region surfaces formed of substantially the same semiconductor-metal alloy, wherein source and drain regions of one transistor of the pair of CMOS transistors include an underlying layer having a different composition of non-dopant elements than underlying layers of the source and drain regions of the other transistor of the pair of CMOS transistors.

18. The semiconductor topography of claim 17, wherein a non-dopant composition of the semiconductor-metal alloy consists essentially of cobalt and silicon.

19. The semiconductor topography of claim 17, wherein the underlying layers of the source and drains regions of the CMOS transistors include different compositions of non-dopant elements than the respective channels of the CMOS transistors.

20. The semiconductor topography of claim 17, wherein the underlying layer of the source and drain regions of the one transistor of the pair of CMOS transistors includes a different lattice constant than underlying layers of the source and drain regions of the other transistor of the pair of CMOS transistors.
